(19) United States
(12) Patent Application Publication
(10) Pub. No.: US 2024/0427230 A1
(43) Pub. Date: Dec. 26, 2024

(54) METHOD OF FORMING PHOTOMASK, LAYOUT PATTERN AND SYSTEM FOR PATTERNING SEMICONDUCTOR SUBSTRATE BY USING PHOTOMASK

(71) Applicant: Fujian Jinhua Integrated Circuit Co., Ltd., Quanzhou City (CN)

(72) Inventor: Joey Xie, Quanzhou City (CN)

(73) Assignee: Fujian Jinhua Integrated Circuit Co., Ltd., Quanzhou City (CN)

(21) Appl. No.: 18/380,667

(22) Filed: Oct. 17, 2023

(30) Foreign Application Priority Data
Jun. 26, 2023 (CN) 202310762744.6

(51) Int. Cl. G03F 1/36; H01L 21/027

(52) U.S. Cl. CPC G03F 1/36; H01L 21/027

(57) ABSTRACT

A method of forming a photomask includes: providing a target pattern; generating a first offset pattern according to the target pattern and a first offset value; generating a second offset pattern according to the first offset pattern and a second offset value; operating the first offset pattern and the second offset pattern with a Boolean operation to obtain a first assist feature; and outputting the target pattern and the first assist feature to form the photomask. The manufacturing time of the resulting photomask can be shortened and fidelity of patterns produced by the photomask can be improved so as to facilitate transfer of the target pattern to the semiconductor substrate precisely.

### BACKGROUND OF THE INVENTION

### 1. Field of the Invention

The present invention generally relates to a technical field of semiconductors, and more particularly to a method of forming a photomask, a layout pattern, and a system for patterning a semiconductor substrate by using a photomask.

### 2. Description of the Prior Art

In current semiconductor manufacturing processes, a layout pattern of an integrated circuit is transferred to a photomask to form a photomask pattern. The photomask pattern is then transferred to a semiconductor substrate through a patterning process. For example, first, a photoresist layer is formed on a semiconductor substrate. Then a photomask pattern is transferred to the photoresist layer in a certain proportion by using a photolithography process to form a photoresist pattern. Afterwards, the semiconductor substrate is etched by using the photoresist as an etching mask to further transfer the photoresist pattern to the semiconductor substrate.

In the process of pattern transfer as described above, when the photomask is exposed to transfer the photomask pattern into the photoresist pattern, a pattern deviation such as corner rounding, line end shortening and line width increasing/decreasing will be caused due to the influence of optical proximity effect (OPE). With the increase of integration density of an integrated circuit, the sizes of components are reduced. As a result, the influence of optical proximity effect is more and more prominent, and thus the performance and yield of products are seriously affected.

For overcoming the above-mentioned problems, optical proximity correction (OPC) is a common practice in the industry. Before the tape-out layout pattern is transferred to the photomask, the original layout pattern is corrected in the computer system according to the rules set according to the updated features of manufacturing processes. Generally speaking, the correction methods include adjusting the line width of the target pattern, modifying the shapes at the ends and corners, adding dummy feature and/or sub-resolution assist features (SRAF) in the open space. After verifying the layout pattern after the optical proximity correction, the corrected layout pattern is transferred to the photomask.

Sub-resolution assist features (SARF) can affect the propagation of light, enhance the contrast and resolution of patterns, and thus enable lithography technology to transfer patterns more faithfully. However, at present, the method of adding sub-resolution assist features (SRAF) to layout patterns consumes a long processing time, and that may conflict with design rules.

### SUMMARY OF THE INVENTION

An object of the present invention is to provide a method of forming a photomask and a layout pattern used for forming the photomask with a shortened pattern-processing time. The obtained photomask has improved pattern fidelity so as to form an ideal target pattern on a semiconductor substrate.

An embodiment of the present invention provides a method of forming a photomask. The method includes the following steps. Firstly, a target pattern is provided, then a first offset pattern is generated according to the target pattern and a first offset value, and then a second offset pattern is generated according to the first offset pattern and a second offset value. Then, the first offset pattern and the second offset pattern are operated with a Boolean operation to obtain a first assist feature. Subsequently, the target pattern and the first assist feature are outputted to form the photomask.

Another embodiment of the present invention provides a layout pattern for forming a photomask, which includes a target pattern and a first assist feature adjacent to the target pattern. The first assist feature extends equidistantly along an edge of the target pattern and includes a closed pattern.

A further embodiment of the present invention provides a system for patterning a semiconductor substrate by using a photomask. The system for patterning a semiconductor substrate includes an IC design system, a computer system and a lithography and etching system. The IC design system provides a target pattern. The computer system executes an optical proximity correction and includes steps of: obtaining the target pattern from the IC design system; generating a first offset pattern according to the target pattern and a first offset value; generating a second offset pattern according to the first offset pattern and a second offset value; and operating the first offset pattern and the second offset pattern with a Boolean operation to obtain a first assist feature. The lithography and etching system obtains the target pattern and the first assist feature from the computer system as a layout pattern of the photomask, and performs a lithography and etching process on the semiconductor substrate by using the photomask.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a flowchart illustrating steps of a method of forming a photomask according to an embodiment of the present invention.

FIG. 2 to FIG. 5 are schematic diagrams illustrating steps of the method of forming a photomask as illustrated in FIG. 1.

FIG. 6 is a flowchart illustrating steps of a method of forming a photomask according to another embodiment of the present invention.

FIG. 7 and FIG. 8 are schematic diagrams illustrating steps of the method of forming a photomask as illustrated in FIG. 6.

FIG. 9 and FIG. 10 are schematic diagrams illustrating layout patterns used for forming photomasks according to embodiments of the present invention.

FIG. 11 is a schematic block diagram illustrating a system for patterning a semiconductor substrate by using a photomask according to an embodiment of the present invention.

### DETAILED DESCRIPTION

For better r understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

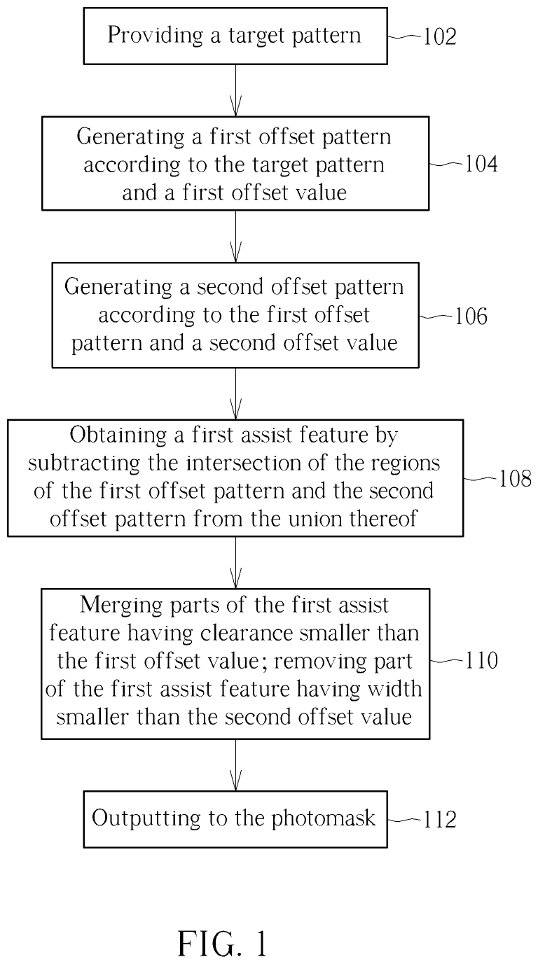

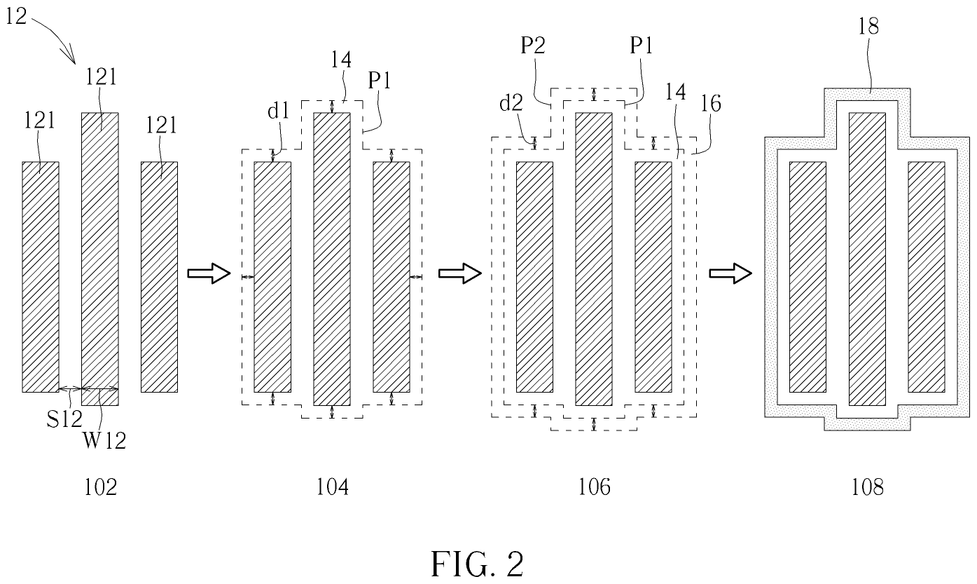

Please refer to FIG. 1 to FIG. 5. FIG. 1 is a flowchart illustrating steps of a method of forming a photomask according to an embodiment of the present invention. FIGS. 2, 3, 4 and 5 are schematic diagrams illustrating steps of the method of forming a photomask as illustrated in FIG. 1. The method is implemented with a computer system that can perform optical proximity correction.

The method of forming a photomask according to the present invention first starts with step 102, providing a target pattern 12 to the computer system. The target pattern 12 is a design layout of an integrated circuit (IC), which can be stored and read by the computer system. Subsequently, the target pattern 12 is transferred to a photomask, and then transferred to a semiconductor substrate through a suitable semiconductor manufacturing process, thereby forming one of the structural layers of the integrated circuit, or forming a material layer (such as a sacrificial layer or a photoresist) temporarily arranged on the substrate. The target pattern 12 may be composed of a plurality of polygon target features, wherein the polygon target features may have the same or different widths, regular or irregular shapes, and at least some of the polygon target features may be connected to or separated from each other. For example, the target pattern 12 shown in FIG. 2 is composed of three separate target features 121, wherein the width W12 of each target feature 121 and the space S12 between them may be the same or different.

The design of the target pattern 12 must conform to the design rule of the process node, so as to ensure that the pattern can be transferred to the semiconductor substrate as expected within the stable process window of lithography and etching process. The minimum design space SO of the target pattern 12 specified in the design specification is the minimum space S12 between the target features 121, and the minimum design width W0 of the target pattern 12 is the minimum width W12 of the target features 121. If the space and width of the target pattern 12 are smaller than the minimum design space S0 and/or the minimum design width W0, the pattern is likely to become abnormal during pattern transfer, resulting in defects such as collapse or bridging. Generally speaking, the minimum design space S0 and the minimum design width W0 are both larger than the minimum resolution space Sr and the minimum resolution width Wr that can be resolved by the photolithography process of the process node.

Next, step 104 is performed to generate a first offset pattern 14 according to the target pattern 12 and a first offset value d1. In some embodiments, the method of generating the first offset pattern 14 may include equidistantly offsetting the edges of each target feature 121 outward by the first offset value d1, and then removing the overlapping parts or intersecting closed-loop parts of the offset edges of adjacent target features 121, thereby obtaining a first offset profile P1 and the first offset pattern 14 defined by the first offset profile P1. In other embodiments, the method of generating the first offset pattern 14 may include expanding the regions of the target features 121 outward by the first offset value d1 equidistantly, and then merging the overlapping parts of the expanded regions to obtain the first offset pattern 14 and its first offset profile P1. The first offset profile P1 is a continuous closed profile, and the first offset pattern 14 is a closed polygon. The first offset profile P1 is substantially parallel to the edges of the target feature 121 and equidistantly separated from the edges of the target feature 121 by the first offset value d1. In some embodiments, the first offset value d1 is equal to the minimum design space S0 of the target pattern 12.

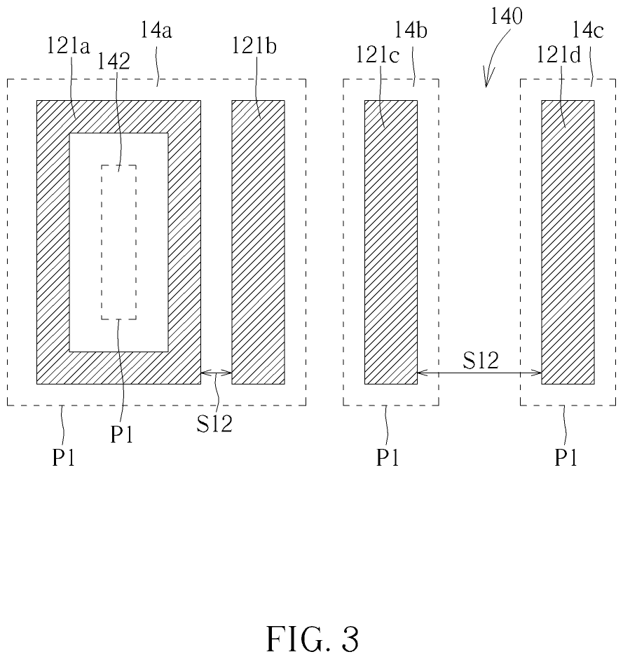

In some embodiments, the first offset pattern 14 is composed of a plurality of polygon portions, wherein the polygonal portions may have the same or different widths and regular or irregular shapes, and gaps may be included between the polygonal portions. The interior of the polygonal portions may include opening patterns. For example, as shown in FIG. 3, when the space S12 between adjacent target features, e.g., the target features 121c and 121d, is more than twice the first offset value d1, a gap 140 will exist between the first offset patterns 14b and 14c generated from the target features 121c and 121d. On the other hand, when the space S12 between adjacent target features, e.g., the target features 121a and 121b, is equal to or less than twice the first offset value d1, the first offset patterns generated from the target features 121a and 121b will be merged into one polygonal first offset pattern 14a. When the target feature 121a includes a closed-loop pattern, and at least a portion inside the closed-loop pattern has a width greater than twice the first offset value d1, the first offset profile P1 generated according to the inner edges of the closed-loop pattern and the first offset value d1 may define at least one opening pattern 142 in the first offset pattern 14a.

Next, step 106 is performed to generate a second offset pattern 16 according to the first offset pattern 14 and a second offset value d2. In some embodiments, the method of generating the second offset pattern 16 may include offsetting the edge of the first offset pattern 14, i.e., the first offset profile P1, outward by a second offset value d2 equidistantly, and then removing the closed-loop parts formed due to intersection of the offset edges of the adjacent target features 121, thereby obtaining a second offset profile P2 and the second offset pattern 16 defined by the second offset profile P2. In other embodiments, the area of the first offset pattern 14 can be expanded outward by the second offset value d2 equidistantly, and meanwhile, the overlapping parts of the expanded areas are merged to obtain the second offset pattern 16 and its second offset profile P2. The second offset profile P2 is a continuous closed profile, and the second offset pattern 16 is a closed polygon. The second offset profile P2 is substantially parallel to the edges of the first offset pattern 14, i.e., the first offset profile P1, and is equidistantly spaced from the first offset profile P1 by the second offset value d2. In some embodiments, the second offset value d2 is less than the minimum design width W0 of the target pattern 12. In some embodiments, the second offset value d2 is also smaller than the minimum resolution width Wr that can be resolved by the photolithography process of the process node.

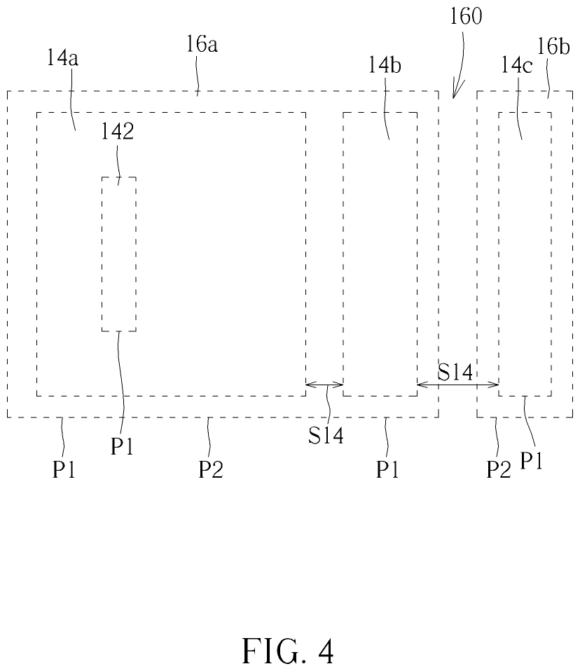

In some embodiments, the second offset pattern 16 is composed of a plurality of polygon portions, wherein the polygonal portions may have the same or different widths and regular or irregular shapes, and gaps may be included between the polygonal portions. The interior of the polygonal portions may include opening patterns. For example, as shown in FIG. 4, when the space S14 between adjacent first offset patterns, e.g., the patterns 14a and 14b, is equal to or less than twice the second offset value d2, the second offset patterns generated from the first offset patterns 14a and 14b, respectively, will be merged into one polygonal second offset pattern 16a. On the other hand, when the space S14 between adjacent first offset patterns, e.g., the patterns 14b and 14c, is more than twice the second offset value d2, a gap 160 will exist between the second offset pattern 16b derived from the first offset pattern 14b and the second offset pattern 16c derived from the first offset pattern 14c. When the width of the opening pattern 142 inside the first offset pattern 14a is less than or equal to twice the second offset value d2, the opening pattern 142 will be eliminated after step 106. That is, no corresponding opening pattern will be formed inside the second offset pattern 16a. When the width of the opening pattern 142 inside the first offset pattern 14a is greater than twice the second offset value d2, after step 106, the second offset profile P2 generated from the edges of the opening pattern 142 may define an opening pattern (not shown) in the second offset pattern 16a.

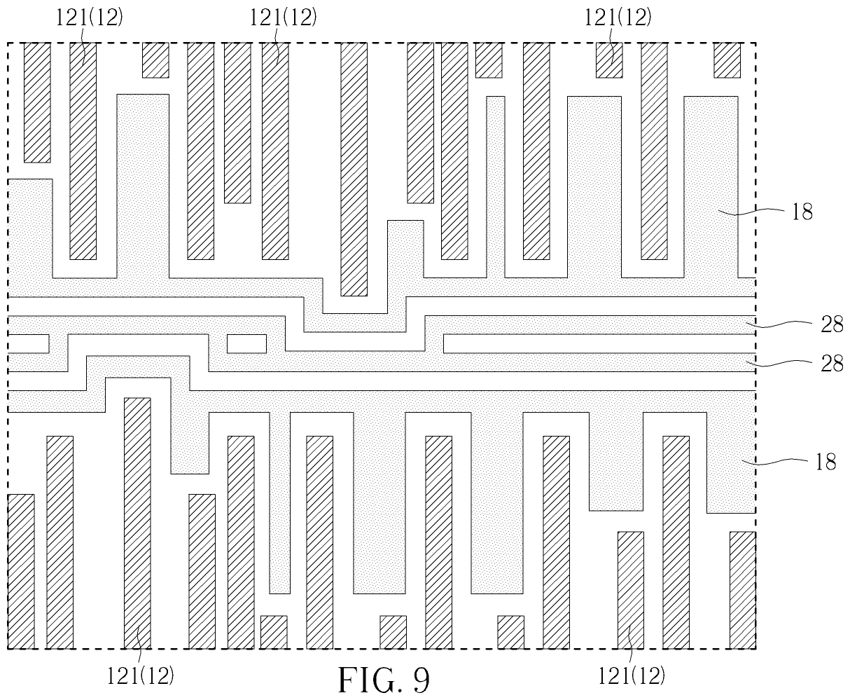

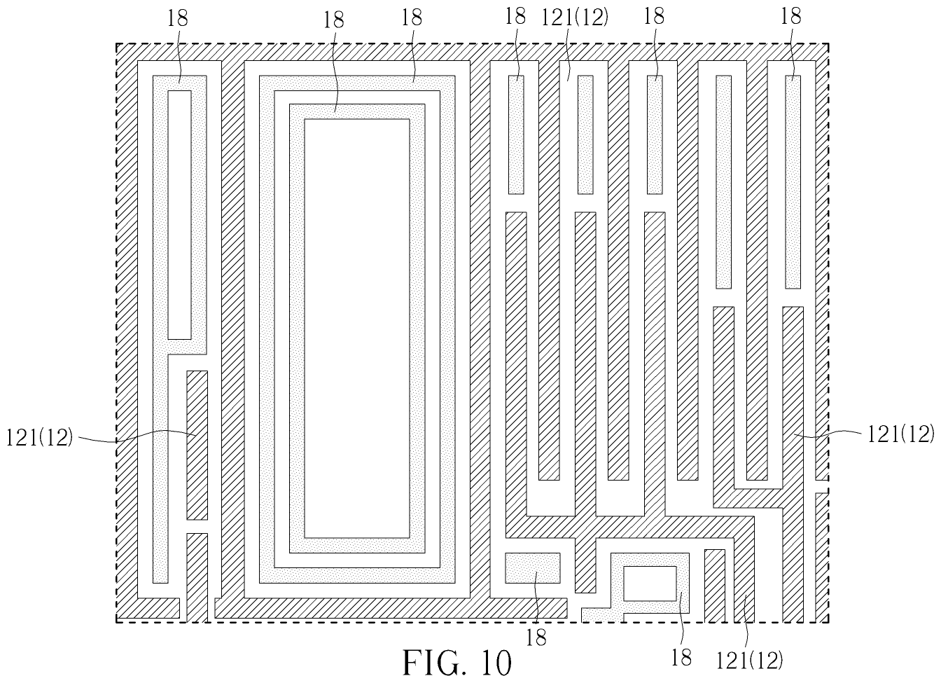

Subsequently, proceed to step 108 to perform Boolean operation on the regions of the first offset pattern 14 and the second offset pattern 16, thereby obtaining a first assist feature 18. For example, the first assist feature 18 can be obtained by subtracting the intersection of the regions of the first offset pattern 14 and the second offset pattern 16 from the union of the regions of the first offset pattern 14 and the second offset pattern 16, or removing the region of the first offset pattern 14 from the region of the second offset pattern 16. As shown in FIG. 2, the first assist feature 18 is located near the edges of the target feature 121, extends parallel to the edges of the target feature 121, and is equidistant from the edges of the target feature 121 by a first offset value d1. In some embodiments, as shown in FIG. 2, the first assist feature 18 includes a closed pattern, such as a closed ring. In some embodiments, as shown in FIGS. 9 and 10, the first assist feature 18 includes a plurality of parts (also called first sub-assist features), wherein each part can be a closed ring or a closed polygon with the same or different widths and regular or irregular shapes. In some embodiments, the first assist feature 18 includes at least two different widths.

Please refer to FIG. 2 again. Optionally, step 110 is performed to adjust the first assist feature 18. The adjustment may include, but is not limited to, removing a part of the first assist feature 18, which has a width smaller than the second offset value d2 and/or merging parts of the first assist feature 18, which have a space therebetween smaller than the first offset value d1.

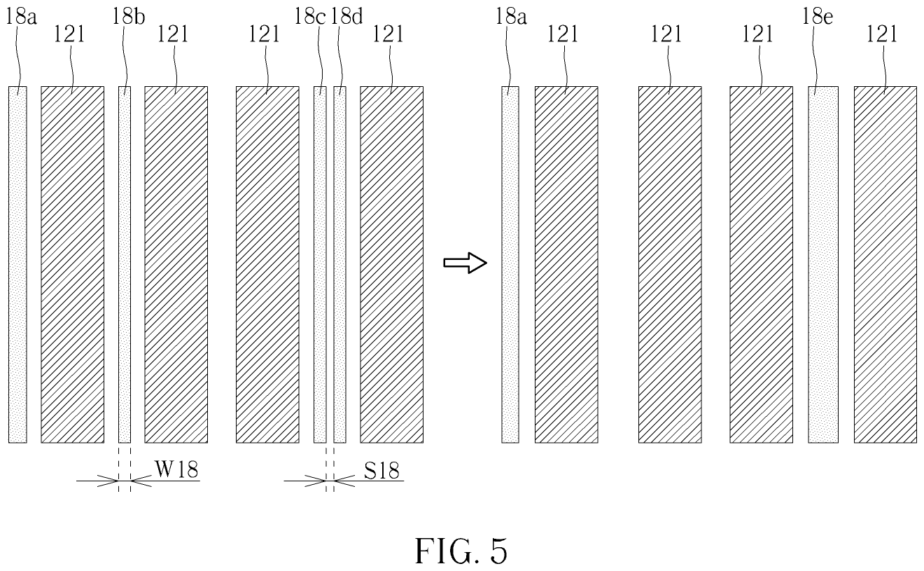

For example, please refer to FIG. 5. The diagram shown in the left side of the figure is a schematic diagram of the first assist feature 18 obtained after step 108 according to an embodiment of the present invention. The first assist feature 18 includes a plurality of parts respectively located near the edges of the target feature 121, e.g., a first sub-assist feature 18a, a first sub-assist feature 18b, a first sub-assist feature 18c and a first sub-assist feature 18d. After step 110, as shown in the right side of FIG. 5, the first sub-assist feature 18b is removed because its width W18 is smaller than the second offset value d2. The first sub-assist feature 18c and the first sub-assist feature 18d are merged into the first sub-assist feature 18e because a space S18 therebetween is smaller than the first offset value d1. By eliminating the parts of the first assist feature 18, which have too small space and/or width, in step 110, the occurrence of violation in layout verification before output to photomask can be ameliorated.

In some embodiments, the minimum design width Wa of the first assist feature 18 adjusted in step 110 (i.e., the minimum value of the width of any part of the first assist feature 18) is equal to the second offset value d2. In other words, the width of any part of the first assist feature 18 adjusted in step 110 is greater than or equal to the second offset value d2 and less than 2d2+d1. In some embodiments, the minimum design width Wa of the first assist feature 18 is less than the minimum design width W0 of the feature pattern 121.

In some embodiments, when the second offset value d2 is smaller than the minimum resolution width Wr, the first assist feature 18 adjusted in step 110 may include both a portion with a width smaller than the minimum resolution width Wr and a portion with a width larger than the minimum resolution width Wr.

In some embodiments, when the first offset value d1 is equal to the minimum design space S0 of the target pattern 12, the width of any part of the first assist feature 18 will be greater than Wa and less than 2Wa+S0.

Next, step 112 is performed to output the target pattern 12 and the first assist feature 18 to the photomask. According to an embodiment of the present invention, the target pattern 12 and the first assist feature 18 define light-transmitting regions on the photomask. Subsequently, a photolithography process is performed using the photomask, and then the target pattern 12 is transferred to be formed on the semiconductor substrate. The first assist feature 18 can enhance the contrast and resolution of the pattern, improve the fidelity of the lithography process, and help to form the ideal target pattern 12 on the semiconductor substrate. In some embodiments, the photomask is preferably matched with a positive photoresist to carry out a photolithography process, so as to ensure that the pattern of the assist feature whose size is relatively small would not collapse to generate pollution particles.

In some embodiments, other optical proximity correction, for example, but not limited to, adjustment of line width, modification of shapes at the ends and corners, and addition of dummy features, may be performed on the target pattern 12 before step 112.

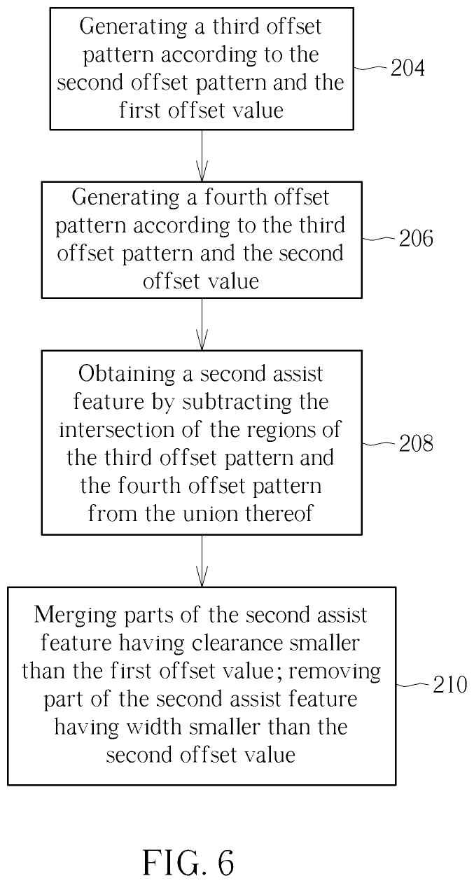

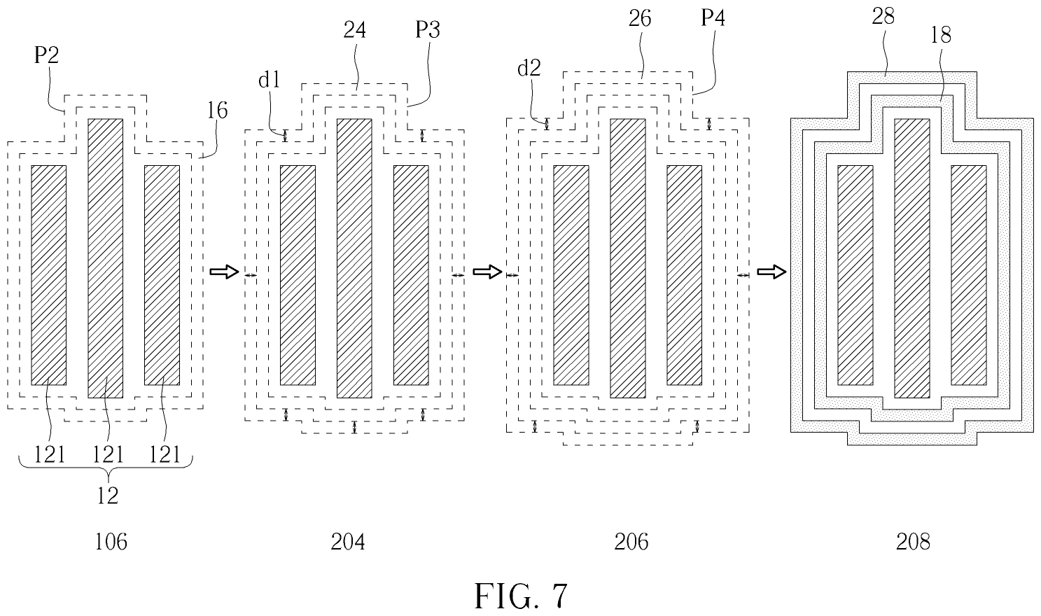

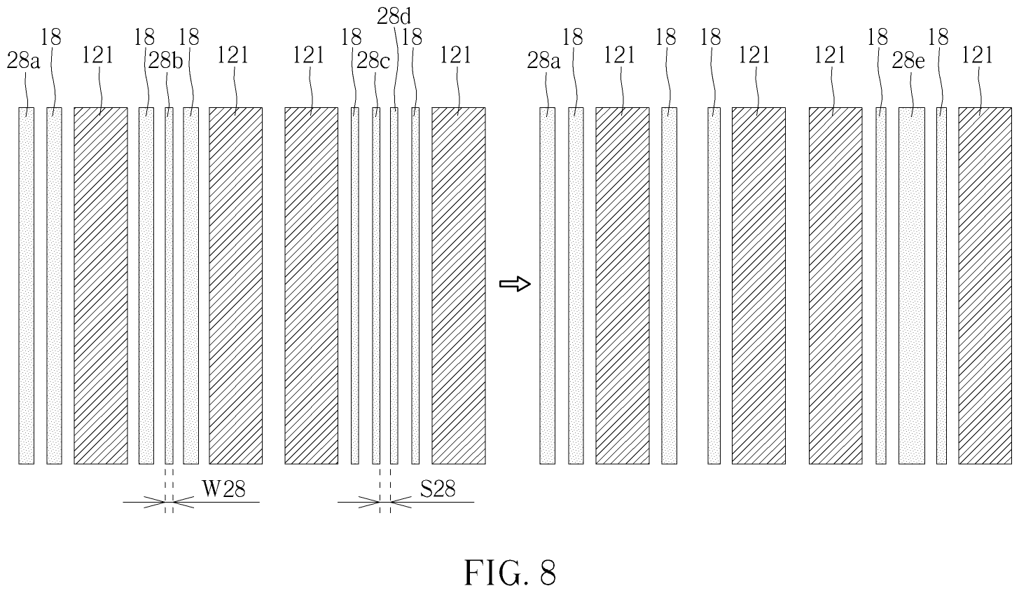

Please refer to FIG. 6, FIG. 7 and FIG. 8. FIG. 6 is a flowchart illustrating steps of a method of forming a photomask according to another embodiment of the present invention. FIG. 7 and FIG. 8 are schematic diagrams illustrating steps of the method of forming a photomask as illustrated in FIG. 6. The step shown in FIG. 6 is performed after step 106 of the method shown in FIG. 1, in order to form a second assist feature 28 near the first assist feature 18, so as to obtain improved optical behavior.

In detail, as shown in FIG. 6, after obtaining the second offset pattern 16 in step 106, step 204 is followed to generate a third offset pattern 24 according to the second offset pattern 16 and the first offset value d1. In some embodiments, the method of generating the third offset pattern 24 may include offsetting the edges of the second offset pattern 16 (i.e., the second offset profile P2), outward by the first offset value d1 equidistantly, and then removing the closed-loop parts formed due to intersection of the offset edges of the adjacent second offset patterns 16 to obtain a third offset profile P3 and the third offset pattern 24 defined by the third offset profile P3. In other embodiments, the area of the second offset pattern 16 can be expanded outward by the first offset value d1 equidistantly, and then the overlapping parts of the expanded areas are merged to obtain the third offset pattern 24 and its third offset profile P3. The third offset profile P3 is a continuous closed profile, and the third offset pattern 24 is a closed polygon. The third offset profile P3 is substantially parallel to the edges of the second offset pattern 16 (i.e., the second offset profile P2), and is equidistantly spaced from the edges of the second offset pattern 16 by the first offset value d1.

In some embodiments, the third offset pattern 24 is composed of a plurality of polygon portions, wherein the polygonal portions may have the same or different widths and regular or irregular shapes, and gaps may be included between the polygonal portions. The interior of the polygonal portions may include opening patterns. For example, when the space between adjacent second offset patterns 16 is more than twice the first offset value d1, a gap (not shown) will exist between the third offset patterns 24 generated from the second offset patterns 16. On the other hand, when the space between adjacent second offset patterns 16 is equal to or less than twice the first offset value d1, the third offset patterns 24 generated from the second offset patterns 16 will be merged into one polygonal third offset pattern 24. When the second offset pattern 16 includes an opening pattern, and the width of the opening pattern is less than or equal to twice the first offset value d1, the opening pattern will be eliminated after step 204. That is, no corresponding opening pattern will be formed inside the third offset pattern 24. When the width of the opening pattern inside the second offset pattern 16 is greater than twice the first offset value d1, after step 204, the third offset profile P3 generated from the inner edges of the opening pattern will may define an opening pattern (not shown) in the third offset pattern 24.

Next, step 206 is performed to generate a fourth offset pattern 26 according to the third offset pattern 24 and the second offset value d2. In some embodiments, the method of generating the fourth offset pattern 26 may include offsetting the edges of the third offset pattern 24 (i.e., the third offset profile P3), outward by the second offset value d2 equidistantly, and then removing the closed-loop parts formed due to intersection of the offset edges of the adjacent third offset patterns 24 to obtain a fourth offset profile P4 and the fourth offset pattern 26 defined by the fourth offset profile P4. In other embodiments, the area of the third offset pattern 24 can be expanded outward by the second offset value d2 equidistantly, and then the overlapping parts of the expanded areas are merged to obtain the fourth offset pattern 26 and its fourth offset profile P4. The fourth offset profile P4 is a continuous closed profile, and the fourth offset pattern 26 is a closed polygon. The fourth offset profile P4 is substantially parallel to the edges of the third offset pattern 24 (i.e., the third offset profile P3), and is equidistantly spaced from the edges of the third offset pattern 24 by the second offset value d2.

In some embodiments, the fourth offset pattern 26 is composed of a plurality of polygon portions, wherein the polygonal portions may have the same or different widths and regular or irregular shapes, and gaps may be included between the polygonal portions. The interior of the polygonal portions may include opening patterns. For example, when the space between adjacent third offset pattern 24 is more than twice the second offset value d2, a gap (not shown) will exist between the fourth offset pattern 26 generated from the third offset pattern 24. On the other hand, when the space between adjacent s third offset pattern 24 is equal to or less than twice the second offset value d2, the fourth offset pattern 26 generated from the third offset pattern 24 will be merged into one polygonal fourth offset pattern 26. When the third offset pattern 24 includes an opening pattern, and the width of the opening pattern is less than or equal to twice the second offset value d2, the opening pattern will be eliminated after step 206. That is, no corresponding opening pattern will be formed inside the fourth offset pattern 26. When the width of the opening pattern inside the third offset pattern 24 is greater than twice the second offset value d2, after step 206, the fourth offset profile P4 generated from the inner edges of the opening pattern may define an opening pattern (not shown) in the fourth offset pattern 26.

Subsequently, proceed to step 208 to perform Boolean operation on the regions of the third offset pattern 24 and the fourth offset pattern 26, thereby obtaining the second assist feature 28. For example, the second assist feature 28 can be obtained by subtracting the intersection of the regions of the third offset pattern 24 and the fourth offset pattern 26 from the union of the regions of the third offset pattern 24 and the fourth offset pattern 26, or removing the region of the third offset pattern 24 from the region of the fourth offset pattern 26. As shown in FIG. 7, the second assist feature 28 is located near the first assist feature 18, extends parallel to the edges of the first assist feature 18, and is equidistant from the edges of the first assist feature 18 by the first offset value d1. In some embodiments, as shown in FIG. 9 and FIG. 10, the second assist feature 28 includes a closed pattern, such as a closed ring. In some embodiments, as shown in FIGS. 9 and 10, the second assist feature 28 includes a plurality of parts (also called second sub-assist features), wherein each part can be a closed ring or a closed polygon with the same or different widths and regular or irregular shapes. In some embodiments, the second assist feature 28 includes at least two different widths.

Please refer to FIG. 6 again. Optionally, step 210 is performed to adjust the second assist feature 28. The adjustment may include, but is not limited to, removing a part of the second assist feature 28, which has a width smaller than the second offset value d2 and/or merging parts of the second assist feature 28, which have a space therebetween smaller than the first offset value d1.

For example, please refer to FIG. 8. The diagram shown in the left side is a schematic diagram of the second assist feature 28 obtained after step 208 according to an embodiment of the present invention. The second assist feature 28 includes a plurality of parts respectively located near the edges of the first assist feature 18, e.g., a second sub-assist feature 28a, a second sub-assist feature 28b, a second sub-assist feature 28c and a second sub-assist feature 28d. After step 210, as shown in the right side of FIG. 8, the second sub-assist feature 28b is removed because its width W28 is smaller than the second offset value d2. The second sub-assist feature 28c and the second sub-assist feature 28d are merged into the second sub-assist feature 28e because a space S28 therebetween is smaller than the first offset value d1. By eliminating the parts of the second assist feature 28, which have too small space and/or width, in step 210, the occurrence of violation in layout verification before output to photomask can be ameliorated.

In some embodiments, the minimum design width Wb of the second assist feature 28 adjusted in step 210 (i.e., the minimum value of the width of any part of the second assist feature 28) is equal to the second offset value d2. In other words, the width of any part of the second assist feature 28 adjusted in step 210 is greater than or equal to the second offset value d2 and less than 2d2+d1. In some embodiments, the minimum design width Wb of the second assist feature 28 is equal to the minimum design width Wa of the first assist feature 18.

In some embodiments, when the second offset value d2 is smaller than the minimum resolution width Wr, the second assist feature 28 adjusted in step 210 may include both a portion with a width smaller than the minimum resolution width Wr and a portion with a width larger than the minimum resolution width Wr.

In some embodiments, when the first offset value d1 is equal to the minimum design space S0 of the target pattern 12, the width of any part of the second assist feature 28 will be greater than Wb and less than 2Wb+S0.

Next, after step 210 shown in FIG. 6, step 112 shown in FIG. 1 is performed to output the target pattern 12, the first assist feature 18 and the second assist feature 28 to the photomask. According to an embodiment of the present invention, all of the target pattern 12, the first assist feature 18 and the second assist feature 28 define light-transmitting regions on the photomask.

FIGS. 9 and 10 are schematic diagrams illustrating layout patterns for forming photomasks according to some embodiments of the present invention. The layout pattern includes a target pattern 12, which includes a plurality of target features 121, a first assist feature 18 located near the edges of the target feature 121, and a second assist feature 28 located near the edges of the first assist feature 18. The first assist feature 18 and the second assist feature 28 may respectively comprise a plurality of parts, wherein the parts may be closed rings or polygons with the same or different widths and regular or irregular shapes.

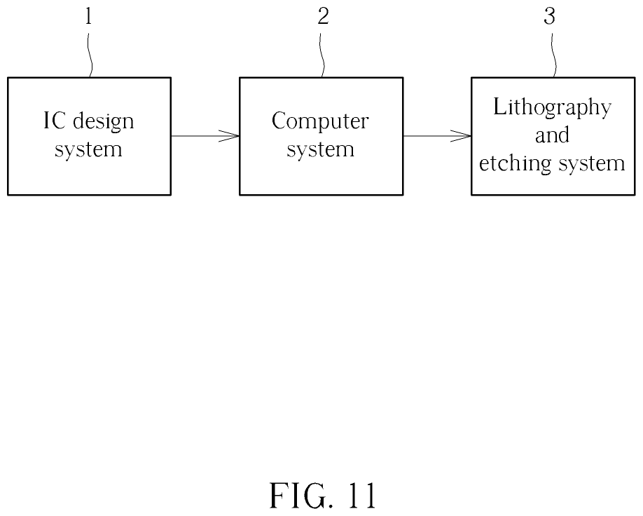

To sum up, according to the present invention, a computer system 2 (see FIG. 11) uses a target pattern designed in and provided by an IC design system 2 and executes an optical proximity correction (OPC) to obtain offset patterns of the target pattern and performs Boolean operation of the offset patterns to generate assist features. The target pattern and the assist features then serve as a layout pattern and are provided for a lithography and etching system 3 to perform a lithography and etching process on the semiconductor substrate with the layout pattern of the photomask. The processing time for generating the layout pattern according to the present invention is shortened in comparison with the prior art method of adding sub-resolution assist features (SRAF). The photomask formed by the layout pattern generated by the computer system according to the method of the present invention can achieve improved pattern contrast and resolution in the photolithography process, and help to transfer the target pattern to the semiconductor substrate precisely.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a photomask, comprising:
providing a target pattern;
generating a first offset pattern according to the target pattern and a first offset value;
generating a second offset pattern according to the first offset pattern and a second offset value;
operating the first offset pattern and the second offset pattern with a Boolean operation to obtain a first assist feature; and
outputting the target pattern and the first assist feature to form the photomask.

2. The method according to claim 1, wherein the target pattern and the first assist feature define a light-transmitting region of the photomask.

3. The method according to claim 1, wherein the first offset value is equal to a minimum design space of the target pattern, and the second offset value is equal to a minimum design width of the first assist feature.

4. The method according to claim 3, wherein the first assist feature comprises a plurality of first sub-assist features, and the method further comprises:
merging parts of the plurality of first sub-assist features, which have a space therebetween smaller than the first offset value.

5. The method according to claim 3, wherein the first assist feature comprises a plurality of first sub-assist features, and the method further comprises:
removing a part of the plurality of first sub-assist features, which has a width smaller than the second offset value.

6. The method according to claim 1, wherein each of the first offset pattern, the second offset pattern and the first assist feature comprises a closed pattern.

7. The method according to claim 1, further comprising:
generating a third offset pattern according to the second offset pattern and the first offset value;
generating a fourth offset pattern according to the third offset pattern and the second offset value;
operating the third offset pattern and the fourth offset pattern with a Boolean operation to obtain a second assist feature; and
outputting the target pattern, the first assist feature and the second assist feature to form the photomask.

8. The method according to claim 7, wherein the first assist feature and the second assist feature define a light-transmitting region of the photomask.

9. The method according to claim 7, wherein the second assist feature comprises a plurality of second sub-assist features, and the method further comprises:
merging parts of the plurality of second sub-assist features, which have a space therebetween smaller than the first offset value.

10. The method according to claim 7, wherein the second assist feature comprises a plurality of second sub-assist features, and the method further comprises:
removing a part of the plurality of second sub-assist features, which has a width smaller than the second offset value.

11. The method according to claim 7, wherein each of the third offset pattern, the fourth offset pattern and the second assist feature comprises a closed pattern.

12. A layout pattern, comprising:
a target pattern; and
a first assist feature adjacent to the target pattern, extending equidistantly along an edge of the target pattern and comprising a closed pattern.

13. The layout pattern according to claim 12, wherein the first assist feature is an irregular pattern comprising at least two different widths.

14. The layout pattern according to claim 12, wherein the target pattern has a minimum design width W0, and the first assist feature has a minimum design width Wa, where Wa is less than W0.

15. The layout pattern according to claim 14, wherein the target pattern has a minimum design space S0, and each part of the first assist feature has a width less than 2Wa+S0.

16. The layout pattern according to claim 12, further comprising a second assist feature adjacent to the first assist feature, extending equidistantly along an edge of the first assist feature and comprising a closed pattern.

17. The layout pattern according to claim 16, wherein the second assist feature is an irregular pattern comprising at least two different widths.

18. The layout pattern according to claim 16, wherein the target pattern has a minimum design space S0, the second assist feature has a minimum design width Wb, and each part of the second assist feature has a width less than 2Wb+S0.

19. The layout pattern according to claim 18, wherein the minimum design width Wb of the second assist feature is equal to the minimum design width Wa of the first assist feature.

20. A system for patterning a semiconductor substrate by using a photomask, comprising:
an IC design system providing a target pattern;
a computer system executing an optical proximity correction and comprising steps of: obtaining the target pattern from the IC design system;
generating a first offset pattern according to the target pattern and a first offset value;
generating a second offset pattern according to the first offset pattern and a second offset value; and
operating the first offset pattern and the second offset pattern with a Boolean operation to obtain a first assist feature; and
a lithography and etching system obtaining the target pattern and the first assist feature from the computer system as a layout pattern of the photomask, and performing a lithography and etching process on a semiconductor substrate by using the photomask.
